(19) United States
(12) Patent Application Publication
(10) Pub. No.: US 2008/0121907 A1
(43) Pub. Date: May 29, 2008

(54) LIGHT EMITTING DIODE AND FABRICATING METHOD THEREOF

(76) Inventors: Way-Jze Wen, Tao-Yung Hsien (TW); Yi-Fong Lin, Tao-Yung Hsien (TW); Huan-Che Tseng, Tao-Yung Hsien (TW); Shyi-Ming Pan, Tao-Yung Hsien (TW); Fen-Ren Chien, Tao-Yung Hsien (TW); Kuo-Ruei Huang, Tao-Yung Hsien (TW); Wen-Joe Song, Tao-Yung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,445

(22) Filed: Aug. 8, 2006

(51) Int. Cl. H01L 33/00

(52) U.S. Cl. 257/94; 257/99; 257/E33.066; 257/E33.023

(57) ABSTRACT

An LED includes a substrate, a first type doping semiconductor layer, a first electrode, a light emitting layer, a second type doping semiconductor layer, a second electrode, a first dielectric layer and a first conductive plug. The first type doping semiconductor layer is formed on the substrate, and the light emitting layer, the second type doping semiconductor layer and the second electrode are formed on a portion of the first type doping semiconductor layer in sequence. The first dielectric layer is formed on another portion of the first type doping semiconductor layer where is not covered by the light emitting layer. The first electrode formed on the first dielectric layer is electrically connected with the first type doping semiconductor layer through the first conductive plug formed in the first dielectric layer. Furthermore, the second electrode is electrically connected with the second type doping semiconductor layer.

### BACKGROUND OF THE INVENTION

1. Field of Invention

The present invention relates to a light emitting device and fabricating method thereof. More particularly, the present invention relates to a light emitting diode (LED) and fabricating method thereof.

2. Description of Related Art

Compared with a conventional bulb, the light emitting diode (LED) has outstanding advantages, such as compact, long-life, low driving voltage/current, cracking resistance, no obvious thermal problem when lighting, mercury free (no pollution problem), high lighting efficiency (power saving), etc. In addition, the lighting efficiency of LEDs has been continuously improved in recent years. Hence, LEDs have gradually replaced fluorescent lamps and incandescent lamps in some fields, such as the scanner light source, the back or front light of the liquid crystal display, the illumination for the instrument panel of automobile, the traffic signal lamps and the general lighting devices.

Furthermore, as the nitrogen-contained III-V compound is a material of wide band gap energy, wherein the wavelength of the emitting light covers from ultraviolet to red light, that is, almost the whole wavelength of the visible light scope. Therefore, LEDs using semiconductor devices contained GaN compounds, such as GaN, GaAlN, GalnN and the like, have been widely applied in various light emitting modules.

FIG. 1 is a schematic cross-sectional view of the conventional LED. Referring to FIG. 1, the LED 100 mainly includes a substrate 110, an n-type doping semiconductor layer 120, an electrode 122, a light emitting layer 130, a p-type doping semiconductor layer 140, a transparent conducting layer 150 and an electrode 142. Wherein, the n-type doping semiconductor layer 120, the light emitting layer 130, the p-type doping semiconductor layer 140, the transparent conducting layer 150 and the electrode 142 are formed on the substrate 110 in sequence. The light emitting layer 130 only covers a portion of the n-type doping semiconductor layer 120, and the electrode 122 is disposed on a portion of the n-type doping semiconductor layer 120 where is not covered by the light emitting layer 130.

Please continue to referring to FIG. 1. The lighting area of the LED 100 mainly depends on the area of the light emitting layer 130, that is, the bigger the area of the light emitting layer 130, the bigger the lighting area of the LED 100. As the light emitting layer 130 and the electrode 122 are all formed on the n-type doping semiconductor layer 120, the area of the electrode 122 must be reduced when increasing the area of the light emitting layer 130. However, when the area of the electrode 122 is too small, the difficulty of fabricating process of the wire bonding may increase; further, the fabricating yield of the LED is compromised.

### SUMMARY OF THE INVENTION

Accordingly, the present invention is directed to provide an LED having big areas for the light emitting layer and electrode simultaneously, so that the lighting area of the LED can be increased and the fabricating yield of the wire bonding of the LED is improved.

Another objective of the present invention is to provide an LED fabricating method to increase the lighting area of the LED without degrading the subsequent fabricating yield of the wire bonding.

The present invention provides an LED structure. The LED includes a substrate, a first type doping semiconductor layer, a light emitting layer, a second type doping semiconductor layer, a first dielectric layer, a first conductive plug, a first electrode and a second electrode. Wherein, the first type doping semiconductor layer is formed on the substrate, and the light emitting layer and the second type doping semiconductor layer are formed on a portion of the first type doping semiconductor layer in sequence. The first dielectric layer is formed on another portion of the first type doping semiconductor layer where is not covered by the light emitting layer. The first electrode formed on the first dielectric layer is electrically connected with the first type doping semiconductor layer through the first conductive plug formed in the first dielectric layer. Furthermore, the second electrode is electrically connected with the second type doping semiconductor layer.

In the preferred embodiment of the present invention, the LED may further include a second dielectric layer formed on a portion of the second type doping semiconductor layer. In one embodiment, the LED may further include a second conductive plug formed in the second dielectric layer. Furthermore, the second electrode formed on the second dielectric layer is electrically connected with the second type doping semiconductor layer through the second conductive plug.

In the preferred embodiment of the present invention, the LED may further include a transparent conducting layer disposed between the second doping semiconductor layer and the second electrode.

In the preferred embodiment of the present invention, the material of the first type doping semiconductor layer, the light emitting layer and the second doping semiconductor layer includes an III-V compound semiconductor material. For example, the material of the first type doping semiconductor layer, the light emitting layer and the second type doping semiconductor layer includes, for example, GaN, GaAlN or GalnN.

In the preferred embodiment of the present invention, the first type doping semiconductor layer is, for example, an n-type doping semiconductor layer, and the second type doping semiconductor layer is, for example, a p-type doping semiconductor layer. Of course, in another embodiment of the present invention, the first type doping semiconductor layer can be, for example, a p-type doping semiconductor layer, and the second type doping semiconductor layer can be, for example, an n-type doping semiconductor layer.

In the preferred embodiment of the present invention, the material of the substrate may include sapphire, carborundum, spinel or silicon.

The present invention also provides an LED fabricating method, including: first, a first type doping semiconductor layer, a light emitting layer, a second type doping semiconductor layer and a mask layer are formed on a substrate in sequence. Wherein, the mask layer exposes a portion of the second type doping semiconductor layer. Next, using the mask layer as mask, the exposed second type doping semiconductor layer and the underneath light emitting layer are removed to expose a portion of the first type doping semiconductor layer. Next, a dielectric material layer is formed on the mask layer and the first type doping semiconductor layer. Next, a portion of the dielectric layer and the mask layer are removed to form a first dielectric layer on another portion of the first type doping semiconductor layer which is not covered by the light emitting layer. Then, a first conductive plug is formed in the first dielectric layer to electrically connect with the first type doping semiconductor layer. Thereafter, a first electrode and a second electrode are formed, respectively. Wherein, the second electrode is electrically connected with the second type doping semiconductor layer, and the first electrode is electrically connected with the first type doping semiconductor layer through the first conductive plug.

In the preferred embodiment of the present invention, the portion of the second type doping semiconductor layer where is not covered by the mask layer and the underneath light emitting layer can be removed by anisotropic etching process.

In the preferred embodiment of the present invention, the method of removing the mask layer and the portion of the dielectric layer, for example, includes: first, forming a patterned photoresist layer on the dielectric layer, wherein the patterned photoresist layer exposes a portion of the dielectric material layer; next, using the patterned photoresist layer as mask, removing the dielectric material layer and the mask layer exposed by the patterned photoresist layer in sequence; thereafter, removing the patterned photoresist layer and the exposed portion of the dielectric layer.

In the preferred embodiment of the present invention, the material of the mask layer includes, for example, nickel, which can be, for example, removed by aqua regia solution.

In the preferred embodiment of the present invention, the material of the dielectric material layer is, for example, silicon oxide, which can be, for example, removed by hydrogen fluoride.

In the preferred embodiment of the present invention, the method of removing the patterned photoresist layer and the exposed portion of the dielectric material layer, for example, includes: first, attaching a diaphragm to the patterned photoresist layer; next, lifting the diaphragm so that the patterned photoresist layer and the exposed portion of the dielectric layer are lifted off with the diaphragm from the substrate.

In the preferred embodiment of the present invention, after the first dielectric layer has been formed and before forming the first electrode and the second electrode, a second dielectric layer can be formed on the substrate in advance to cover a portion of the second type doping semiconductor layer. Then, a second conductive plug is formed on the second dielectric layer, accordingly, the second electrode formed subsequently is electrically connected with the second type doping semiconductor layer through the second conductive plug.

In the preferred embodiment of the present invention, after the first dielectric layer has been formed and before forming the second electrode, a transparent conducting layer is formed on the second type doping semiconductor layer.

In the present invention, a first dielectric layer is disposed between the first electrode and the first type doping semiconductor layer, and the first electrode is electrically connected with the first type doping semiconductor layer through the first conductive plug; accordingly, the resistance between the first electrode and the first type doping semiconductor layer is reduced, and the electrical characteristics of the LED is improved.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional LED.

FIGS. 2A to 2F are schematic cross-sectional fabricating flow charts of the LED according to the embodiment of the present invention.

FIGS. 3A to 3D are the cross-sectional views of the flow chart of forming the structure as shown in FIG. 2D.

FIG. 4 is a cross-sectional view of the LED according to another embodiment of the present invention.

FIG. 5 is a cross-sectional view of an LED according to another embodiment of the present invention.

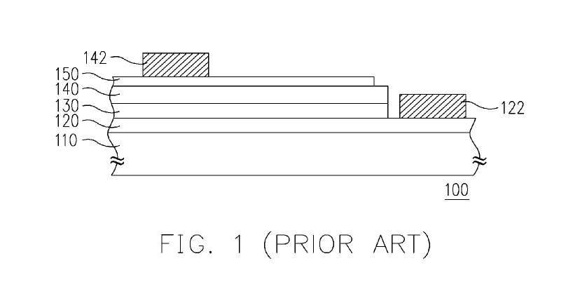

### DESCRIPTION OF EMBODIMENTS

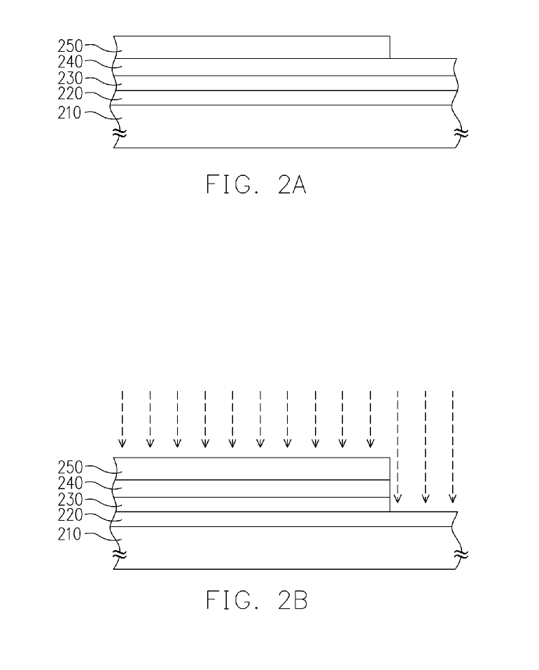

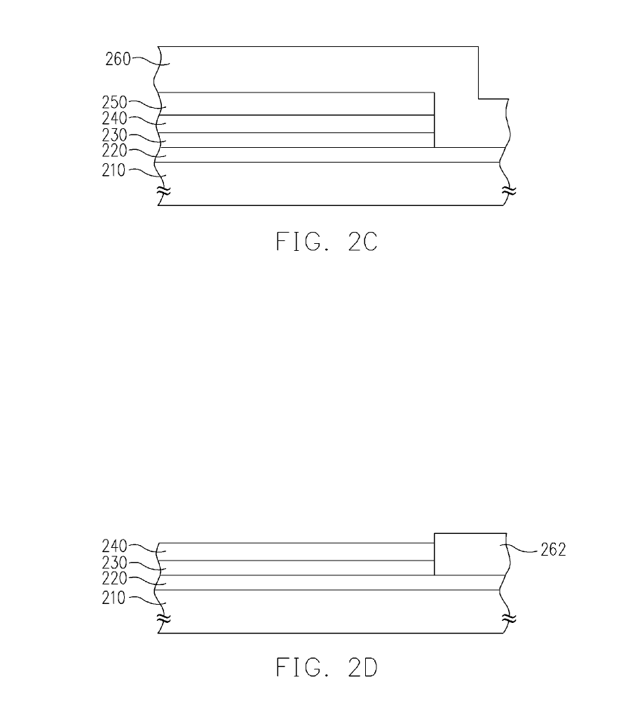

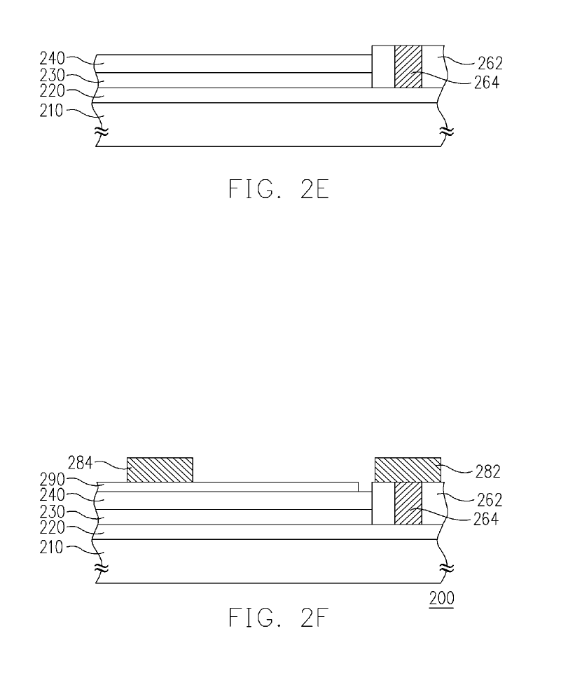

FIGS. 2A to 2F are schematic cross-sectional fabricating flow charts of the LED according to the embodiment of the present invention. Referring to FIG. 2A, first, a first type doping semiconductor layer 220, a light emitting layer 230, a second type doping semiconductor layer 240 and a mask layer 250 are formed on the substrate 210 in sequence. Wherein, the mask layer 250 exposes a portion of the second type doping semiconductor layer 240.

As above, the material of the substrate 210 is, for example, sapphire, carborundum, spinel or silicon. The materials of the first type doping semiconductor layer 220, the light emitting layer 230 and the second type doping semiconductor layer 240 are, for example, III-V compound semiconductor material, and the most common materials used are GaN, GaAlN or GalnN. In the embodiment, the first type doping semiconductor layer 220 is, for example, an n-type doping semiconductor layer, and the second type doping semiconductor layer 240 is, for example, a p-type doping semiconductor layer. However, in other embodiments of the present invention, the first type doping semiconductor layer 220 can be, for example, a p-type doping semiconductor layer, and the second type doping semiconductor layer 240 can be, for example, an n-type doping semiconductor layer. In addition, the material of the mask layer 250 is, for example, nickel.

Next, referring to FIG. 2B, using the mask layer 250 as mask, the exposed portion of the second type doping semiconductor layer 240 and a portion of the light emitting layer 230 are removed to expose a portion of the first type doping semiconductor layer 220. In the embodiment, the portion of the second type doping semiconductor layer 240 where is exposed by the mask layer 250 and the underneath light emitting layer 230 can be removed by anisotropic etching process. For example, the anisotropic etching process is, for example, reaction ion etching (RIE) process.

Next, referring to FIG. 2C, a dielectric material layer 260 is formed on the substrate 200 to cover the mask layer 250 and the first doping semiconductor layer 220. Wherein, the material of the dielectric material layer 260 is, for example, silicon oxide. Next, referring to FIG. 2D, the mask layer 250 and a portion of the dielectric material layer 260 are removed to form a first dielectric layer 262 on the portion of the first type doping semiconductor layer 220 where is exposed by the mask layer 250. The following will describe the forming process of the first dielectric layer 262 in detail, but the present invention is not limited by it.

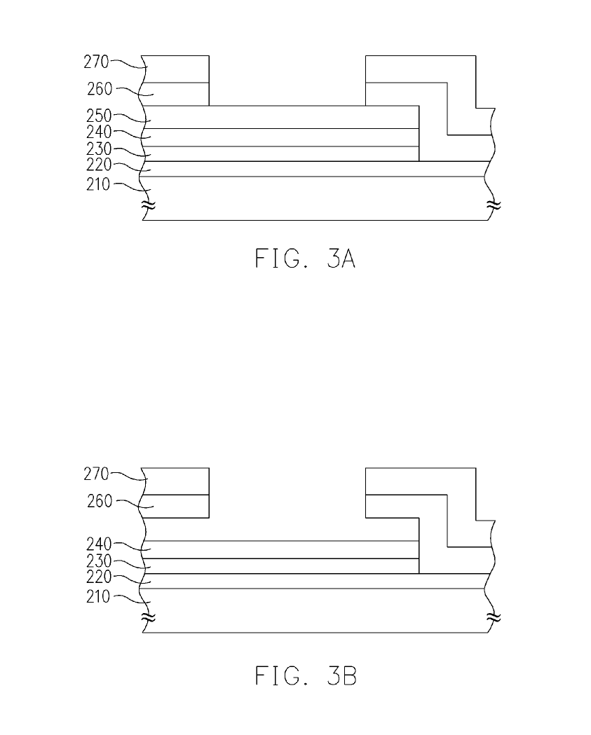

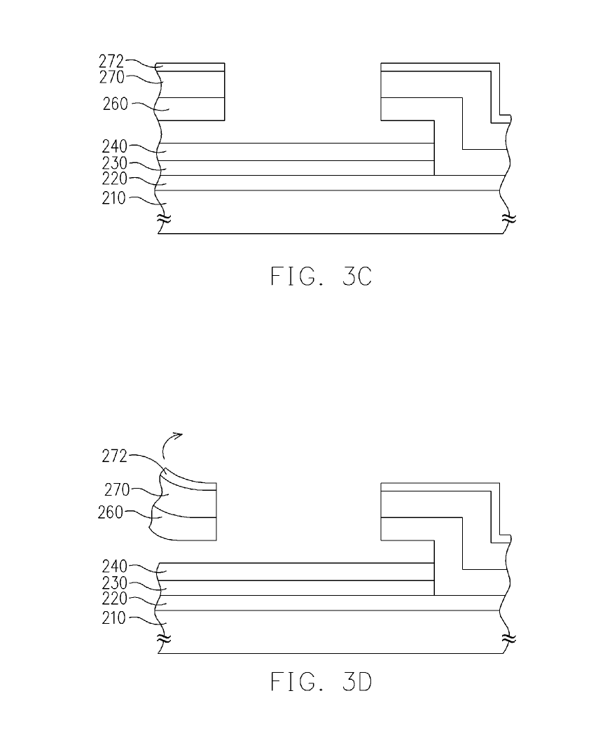

FIGS. 3A to 3D are the cross-sectional views of the flow chart of forming the structure as shown in FIG. 2D. Referring to FIG. 3A, according to the embodiment, first, a patterned photoresist layer 270 is formed on the dielectric material layer 260; next, using the patterned photoresist layer 270 as mask, the portion of the dielectric material layer 260 where is exposed by the patterned photoresist layer 270 is removed. In the step, a wet etching process can be performed by HF solution to remove the dielectric material layer 260 which is composed of SiO₂ in the embodiment. Referring to FIG. 3B, after the exposed dielectric material layer 260 has been removed, the mask layer 250 is then removed. In the step, a wet etching process can be performed by aqua regia solution to remove the mask layer 250 which is composed of nickel in the embodiment.

Finally, the patterned photoresist layer 270 and a portion of the dielectric material layer 260 that is not etched are removed; accordingly, a first dielectric layer 262 as shown in FIG. 2D is formed on the first type doping semiconductor layer 220. It is remarkable that the patterned photoresist layer 270 is removed by, for example, lift-off so that the portion of the dielectric material layer 260 and the patterned photoresist layer 270 are removed together from the substrate 210. For example, referring to FIG. 3C, in the embodiment, first, attaching a diaphragm 272 to the patterned photoresist layer 270; next, as shown in FIG. 3D, lifting-off the diaphragm 272 from the substrate 210 so that the patterned photoresist layer 270 and a portion of the dielectric material layer 260 are lifted-off together with the diaphragm 272 from the substrate 210, and the structure in FIG. 2D is formed.

Referring to FIG. 2E, after the first dielectric layer 262 is formed, a first conductive plug 264 is then formed in the first dielectric layer 262, accordingly, the first conductive plug 264 is electrically connected to the first type doping semiconductor layer 220. Wherein, the first conductive plug 264 is, for example, formed by vapor deposition. Next, referring to FIG. 2F, a first electrode 282 and a second electrode 284 are formed, wherein the material of the first electrode 282 and the second electrode 284 is, for example, aluminum or other conductive material with high reflective factor. Here, as the first electrode 282 formed on the first dielectric layer 262 is electrically connected with the first type doping semiconductor layer 220 through the first conductive plug 264, there is better electrical connection between the first electrode 282 and the first type doping semiconductor layer 220 compared with the prior art. Thus, the reliability of the first electrode 282 is improved.

It is remarkable that, as shown in FIG. 2F, before forming the second electrode 284, a transparent conducting layer 290 can be formed on the second type doping semiconductor layer 240 in advance to improve the transmission uniformity of the current in the first type doping semiconductor 220, the light emitting layer 230 and the second type doping semiconductor layer 240. Wherein, the material of the transparent conducting layer 290 is, for example, indium tin oxide (ITO) or indium zinc oxide (IZO). The second electrode 284 according to the embodiment formed on the transparent conducting layer 290 is electrically connected with the second type doping semiconductor layer 240 through the transparent conducting layer 290.

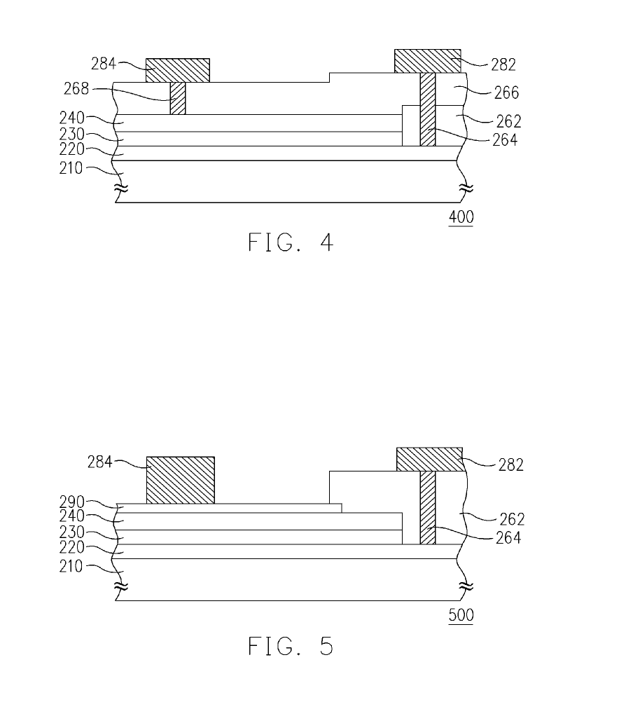

In particular, referring to FIG.4, according to another embodiment of the present invention, after the first dielectric layer 262 has been formed and before forming the first conductive plug 264, a second dielectric layer 266 can be formed on the substrate 210 to cover the first dielectric layer 262 and the second type doping semiconductor layer 240. Then, while the first conductive plug 264 is being formed, a second conductive plug 268, which is electrically connected with the second type doping semiconductor layer 240, is formed in the second dielectric layer 266 simultaneously. Thereafter, as the above description of the embodiment, the first electrode 282 and the second electrode 284 are formed and electrically connected with the first type doping semiconductor layer 220 and the second type doping semiconductor layer 240, respectively. It should be noted that the first conductive plug 264 of the embodiment is electrically connected with the first type doping semiconductor layer 220 by passing through the first dielectric layer 262 and the second dielectric layer 266.

Referring to FIG. 4, as the first electrode 282 is formed on the second dielectric layer 266 in the embodiment, the area of the light emitting layer 230 can be enlarged without shrinking the area of the first electrode 282, and thus the lighting area of the LED 400 is increased. Furthermore, in the real fabricating process, if the area of the first electrode 282 needs to be enlarged to improve the yield of the subsequent wire-bonding process, it will not impact the lighting area of the LED 400. In other words, the LED 400 can have big lighting area and high fabricating yield of the wire-bonding process simultaneously.

After the first electrode 282 and the second electrode 284 are formed, the fabricating processes of the LED 200 are almost completed. The subsequent processes are well known by those skilled in the art so that the detailed description is omitted here.

The following will describe the structure of the LED of the present invention in detail using the LED 200 in FIG. 2F as an example so that those skilled in the art can understand the characteristics of the present invention more clearly.

Referring to FIG. 2F, the LED 200 mainly includes a substrate 210, a first type doping semiconductor layer 220, a light emitting layer 230, a second type doping semiconductor layer 240, a first dielectric layer 262, a first conductive plug 264, a first electrode 282 and a second electrode 284. Wherein, the first type doping semiconductor layer 220 is formed on the substrate 210, and the light emitting layer 230 and the second type doping semiconductor layer 240 are formed on a portion of the first type doping semiconductor layer 220 in sequence. The first dielectric layer 262 is formed on a portion of the first type doping semiconductor layer 220 where is uncovered by the light emitting layer 230.

As above, the first electrode 282 formed on the first dielectric layer 262 is electrically connected with the first type doping semiconductor layer 220 through the first conductive plug 264 disposed in the first dielectric layer 262. The second electrode 284 is electrically connected with the second type doping semiconductor layer 240; and for example, the second electrode 284 is electrically connected with the second doping semiconductor layer 240 through the transparent conducting layer 290 disposed on the second type doping semiconductor layer 240. Here, as the first electrode 282 of the LED 200 is electrically connected with the first type doping semiconductor layer 220 through the first conductive plug 264, the resistance between the first electrode 282 and the first type doping semiconductor layer 220 can be reduced.

It is remarkable that, in other embodiments of the present invention, as shown in FIG. 4, a second dielectric layer 266 is formed on the first dielectric layer 262, and the first electrode 264 formed on the second dielectric layer 266 is electrically connected with the first type doping semiconductor layer 220 through the first conductive plug 264 passing through the second dielectric layer 266 and the first dielectric layer 262. Or, as shown in FIG. 5, the first dielectric layer 262 may cover a portion of the second type doping semiconductor layer 240. Accordingly, without the degradation of the area of the light emitting layer 230, the area of the predefined region of the first electrode 282 can be enlarged. Further, the enlarged area of the first electrode 282 is advantageous for performing the subsequent wire-bonding process.

It should be noted that the first dielectric layer 262 and the second dielectric layer 266 in FIG. 4 are be formed in different fabricating processes as the above description. However, in other embodiments of the present invention, the first dielectric layer 262 and the second dielectric layer 266 can be formed by the same membrane layer in the same fabricating process, but the present invention does not limit it.

Moreover, those skilled in the art should know that, the fabricating process of the LED 500 in FIG. 5 includes: for example, first, a first type doping semiconductor layer 220, a light emitting layer 230, a second type doping semiconductor layer 240 and a transparent conducting layer 290 are formed on the substrate 210 in sequence; next, a first dielectric layer 262 is formed to cover the first type doping semiconductor layer 220 and a portion of the second type doping semiconductor layer 240. Wherein, the first dielectric layer 262 is, for example, formed by photolithography and etching. The subsequent fabricating processes of forming the first conductive plug 264, the second conductive plug 268, the first electrode 282 and the second electrode 284 are the same as the above embodiment, so that the detailed description for those is omitted here.

In summary, in the present invention, a first dielectric layer is disposed between the first electrode and the first type doping semiconductor layer; accordingly, the first electrode is electrically connected with the first type doping semiconductor layer through the first conductive plug disposed in the first dielectric layer. Further, the resistance between the first electrode and the first type doping semiconductor layer is reduced, and the electrical characteristics of the LED are improved.

Moreover, as the first electrode of the LED of the present invention is not formed on the first type doping semiconductor layer, the area of the light emitting layer can be enlarged without degrading the area of the first electrode. Thus, the lighting area of the LED is enlarged. In another view, the present invention can increase the area of the first electrode without shrinking the area of the light emitting layer, thus, the fabricating yield of the subsequent wire-bonding process is improved.

In conclusions, compared with the conventional technique, the LED of the present invention not only has bigger lighting area, but also has bigger electrode area. As a result, the LED of the present invention can increase the lighting area and improve the fabricating yield of the wire-bonding process simultaneously.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A light emitting diode (LED), including:
a substrate;
a first type doping semiconductor layer, formed on the substrate;
a light emitting layer, formed on a portion of the first type doping semiconductor layer;
a second type doping semiconductor layer, formed on the light emitting layer;
a first dielectric layer, formed on another portion of the first type doping semiconductor layer where is not covered by the light emitting layer;
a first conductive plug, passing through the first dielectric layer and electrically connected with the first type doping semiconductor layer;
a first electrode, formed on the first dielectric layer and electrically connected with the first type doping semiconductor layer through the first conductive plug; and
a second electrode, electrically connected with the second type doping semiconductor layer.

2. The LED as claimed in claim 1, further includes a second dielectric layer formed on a portion of the second type doping semiconductor layer.

3. The LED as claimed in claim 2, further includes a second conductive plug formed in the second dielectric layer, wherein the second electrode is electrically connected with the second type doping semiconductor layer through the second conductive plug.

4. The LED as claimed in claim 1, further includes a transparent conducting layer disposed between the second doping semiconductor layer and the second electrode.

5. The LED as claimed in claim 1, wherein the material of the first type doping semiconductor layer, the light emitting layer and the second doping semiconductor layer includes III-V compound semiconductor material.

6. The LED as claimed in claim 5, wherein the III-V compound semiconductor material includes GaN, GaAIN or GaInN.

7. The LED as claimed in claim 1, wherein the first type doping semiconductor layer is an n-type doping semiconductor layer, and the second type doping semiconductor layer is a p-type doping semiconductor layer.

8. The LED as claimed in claim 1, wherein the first type doping semiconductor layer is a p-type doping semiconductor layer, and the second type doping semiconductor layer is an n-type doping semiconductor layer.

9. The LED as claimed in claim 1, wherein the material of the substrate includes sapphire, carborundum, spinel or silicon.

10-17. (canceled)
